(19) United States
(12) Patent Application Publication
(10) Pub. No.: US 2026/0157119 A1
(43) Pub. Date: Jun. 4, 2026

(54) NONVOLATILE MULTIBIT MONOLITHICALLY INTEGRATED PROGRAMABLE METASURFACE

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/968,819

(22) Filed: Dec. 4, 2024

(51) Int. Cl. H10N 70/20; H04B 7/04; H10N 70/00

(52) U.S. Cl. CPC H10N 70/231; H04B 7/04013; H10N 70/8613; H10N 70/8828

(57) ABSTRACT

The technology described herein is directed towards a reconfigurable intelligent surface (metasurface) design and implementation in which phase change (chalcogenide) material is (e.g., monolithically) integrated in each unit cell of the reconfigurable intelligent surface. The conductive or nonconductive states of the phase change (chalcogenide) material can be individually controlled (thermally-pulsed) per unit cell, which determines the phase of the unit cell based on the unit cell's conductive or nonconductive phase change material until subsequently pulsed, without needing continuous applied power. For example, with three phase change elements per unit cell, eight different state combinations can be controllably achieved, whereby dynamic reconfiguration of the reconfigurable intelligent surface to a given phase profile can be used to beamform a reflected beam in one shape and direction, and then to a different phase profile that changes the unit cells' states to beamform another reflected beam in another shape and/or direction.

### RELATED APPLICATION

The subject patent application is related to U.S. patent application Ser. No. _______, filed _______, and entitled “RECONFIGURABLE METASURFACE WITH INTEGRATED SIGNAL READOUT MECHANISM” (docket no. 140762.01/DELLP1393US), the entirety of which patent application is hereby incorporated by reference herein.

### BACKGROUND

Reconfigurable intelligent surfaces (alternatively referred to as intelligent reflective surfaces, or metasurfaces) are manmade thin reflective or refractive surfaces whose electromagnetic response can be electronically controlled. Reconfigurable intelligent surfaces are characterized by their two-dimensional arrays of electronically controllable reflecting elements that can dynamically manipulate electromagnetic waves by altering attributes such as phase, amplitude, and direction of the incoming signal. Because of their ability to alter the attributes of signals reflected at the surface, intelligent reflective surfaces are being evaluated for use in beyond fifth generation (B5G) and sixth generation (6G) wireless communication and wireless sensing networks.

The traditional approach of using PIN diodes and varactors for reconfigurable intelligent surface reconfigurability comes with significant drawbacks. For example, such components are prone to high losses, parasitic effects, and limited phase tunability, which hinder the overall performance and scalability of metasurfaces. Moreover, their reliance on continuous power supply, along with the complexities of soldering and biasing in dense arrays, further complicates their integration into reconfigurable intelligent surfaces.

### BRIEF DESCRIPTION OF THE DRAWINGS

The technology described herein is illustrated by way of example and not limited to the accompanying figures in which like reference numerals indicate similar elements and in which:

FIG. 1 is an example conceptual block diagram showing an example system that includes a unit cell of a reconfigurable intelligent surface for reflecting an incoming electromagnetic signal, in accordance with various example embodiments and implementations of the subject disclosure.

FIG. 2A is a three-dimensional (3D) view representation of an example unit cell, in accordance with various example embodiments and implementations of the subject disclosure.

FIGS. 2B and 2C show a two-dimensional (2D) top view and a 2D bottom view, respectively, of an example unit cell, in accordance with various example embodiments and implementations of the subject disclosure.

FIG. 3 is a 3D view representation of an example metasurface of unit cells, in accordance with various example embodiments and implementations of the subject disclosure.

FIG. 4 is a 3D exploded representation of an example unit cell, in accordance with various example embodiments and implementations of the subject disclosure.

FIG. 5 is a 2D exploded side-view representation of an example unit cell, in accordance with various example embodiments and implementations of the subject disclosure.

FIG. 6 is a 3D exploded view representation of the upper portion of an alternative example unit cell that includes rectangular components, in accordance with various example embodiments and implementations of the subject disclosure.

FIGS. 7A, 7B, 8A and 8B show how a heater can change the states of a phase change material with applied voltage or current pulses, in accordance with various example embodiments and implementations of the subject disclosure.

FIG. 9 is representation of an example unit cell, showing different states corresponding to different conductive and nonconductive signal chalcogenide rings of the unit cells, in accordance with various example embodiments and implementations of the subject disclosure.

FIG. 10 is representation of an example scenario setup for power and beam distribution, in accordance with various example embodiments and implementations of the subject disclosure.

FIGS. 11A, 11B, 12A and 12B show gain and co-/cross-polarization performance results of an example simulation, in accordance with various example embodiments and implementations of the subject disclosure.

FIGS. 13A, 13B, 14A and 14B show example simulation gain and feed distance variation analysis for θ=30° and φ=15°, in accordance with various example embodiments and implementations of the subject disclosure.

FIGS. 15A and 15B show electromagnetic (EM) analyzed gain (dB, FIGS. 13A, 13B) performance results of an example simulation at different φ° for different feed locations, in accordance with various example embodiments and implementations of the subject disclosure.

FIGS. 16A, 16B, 16C, 17A, 17B and 17B show example power and beam distribution plots of an example simulation at various distances, in accordance with various example embodiments and implementations of the subject disclosure.

FIG. 18 is a flow diagram showing example operations related to changing phase shift of a unit cell by controlling individual elements of a heater network, in accordance with various example embodiments and implementations of the subject disclosure.

### DETAILED DESCRIPTION

The technology described herein is generally directed towards a reconfigurable intelligent surface (metasurface) based on phase change material to reconfigurable form metasurface patterns (phase profiles) to redirect incoming signals as beamformed beams. Phase change materials have the ability to switch between conductive and insulating states upon the application of an electrical pulse, allowing for dynamic reconfiguration of the metasurface.

In one implementation, the phase change material is monolithically integrated into each unit cell pf the reconfigurable intelligent surface with a resistive heating matrix (network of heating elements), which serves as the only active element in the structure, significantly simplifying the control mechanism. This also eliminates the need for continuous power supply while overcoming prior issues of high losses, parasitic effects, and limited phase tunability.

Thus, the phase change material alloy can switch between amorphous (insulating) and crystalline (conductive) states when subjected to localized heating per unit cell. the reflective pattern of each unit cell is formed and altered dynamically as needed by actuating specific heaters, making the reconfigurable intelligent surface real-time reconfigurable. In other words, the use of the phase change and heater arrays enables the metasurface to adapt its reflective properties in real-time, such as to optimize signal direction and phase near-continuously, responding to the current conditions of the dynamic wireless environment. The switching time of the material between states is in nanoseconds, hence the total reconfiguration time of the end-to-end surface can be under sub-microseconds regime.

In this way, the reconfigurable intelligent surface described herein beamforms a reflected signal in a passive way by varying the unit cells' phases to redirect incoming energy towards specific users or regions, without the need for active components. This is unlike traditional beamforming that requires phased array antennas, which can be complex and power consuming.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

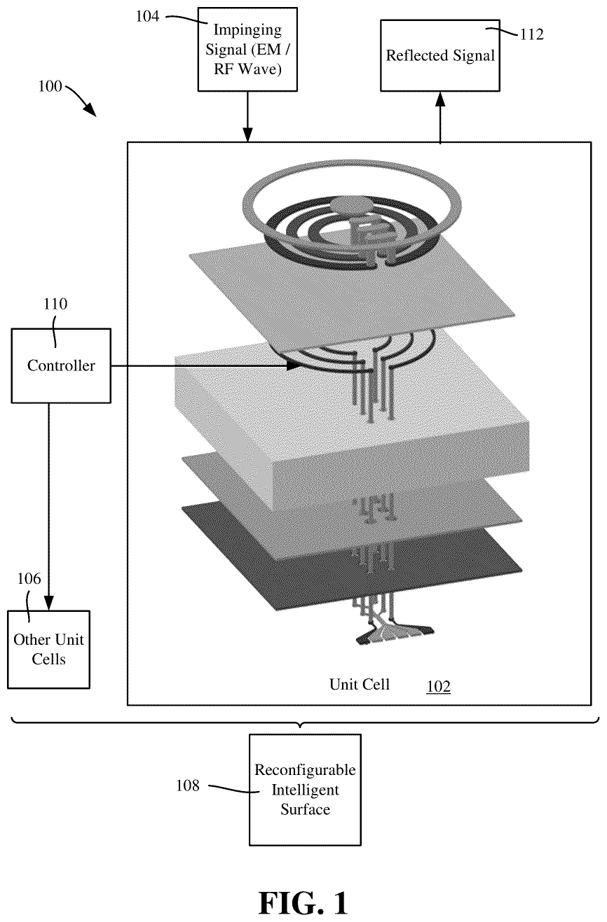

FIG. 1 is a conceptual depiction of an example system 100 including a unit cell 102 that redirects (e.g., reflects) an impinging (incoming) signal 104. The unit cell 102, in conjunction with other unit cells 106, form a reconfigurable intelligent surface 108.

The reconfigurable intelligent surface 108 is coupled to or otherwise incorporates a controller 110 that controls the phase shifts of the unit cell 102 and the other unit cells 106. This allows the incoming electromagnetic wave/signal 104 to be reflected as a beam 112 that can be shaped and steered in a desired direction. This can be based on having real time or near real-time information of the channel (network conditions).

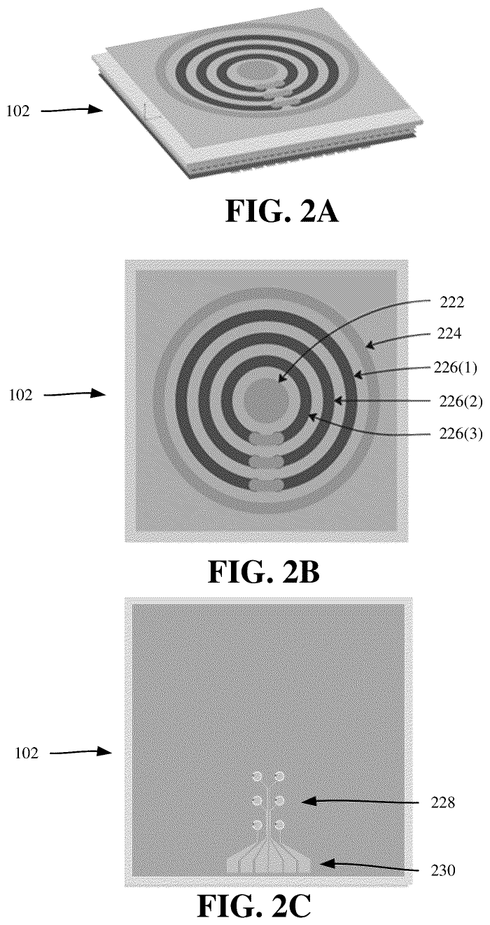

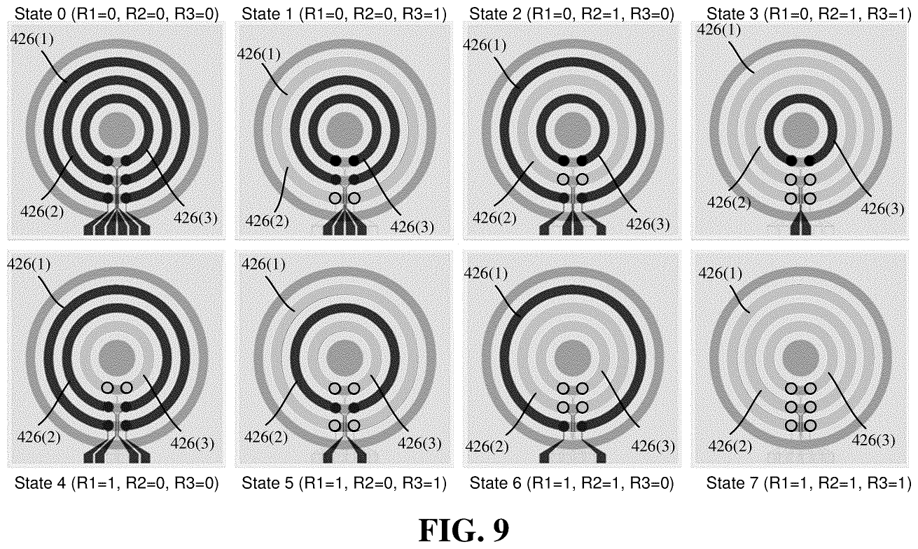

Described herein is one example unit cell element with nonvolatile phase change material-based beamforming capability, which can be monolithically integrated; examples of such unit cells are depicted in FIGS. 1-2C , and 4-6. More particularly, FIG. 2A is a three-dimensional (3D) view of the unit cell 102 of FIG. 1. FIG. 2B is a two-dimensional (2D) view top view showing various components of the unit cell as viewed from above, including an inner metallic patch 222, and outer metallic ring 224 and inner penannular rings 226(1)-226(2). Note that while three such inner penannular rings 226(1)-226(2) are depicted, which are controllably switched between conductive and nonconductive states as described herein to change the phase response of the unit cell 102, this is a nonlimiting example, and any practical number of such phase change components can be present in a given unit cell. Further note that the number of state-changeable inner penannular rings, N, can change the phase in 2^{N} ways, that is, one inner ring allows for two combinations corresponding to two different phases, two inner rings allow for four combinations corresponding to four different phases, three inner rings allow for eight combinations corresponding to eight different phases, and so on, as described herein with reference to FIG. 9. Still further, note that alternatively, instead of separate inner penannular ring areas 226(1)-226(2), there can be one phase change material layer, with the heaters positioned to heat the phase change material layer in individual portions corresponding to the separate inner penannular ring areas.

FIG. 2B is a 2D bottom view showing various components of the unit cell as viewed from below, including interconnects to a heater network of refractory heaters (collectively labeled) 228. The contact pads (collectively labeled) 230 per unit cell (e.g., 102) facilitate coupling of the heaters to control voltage (or current) pulses.

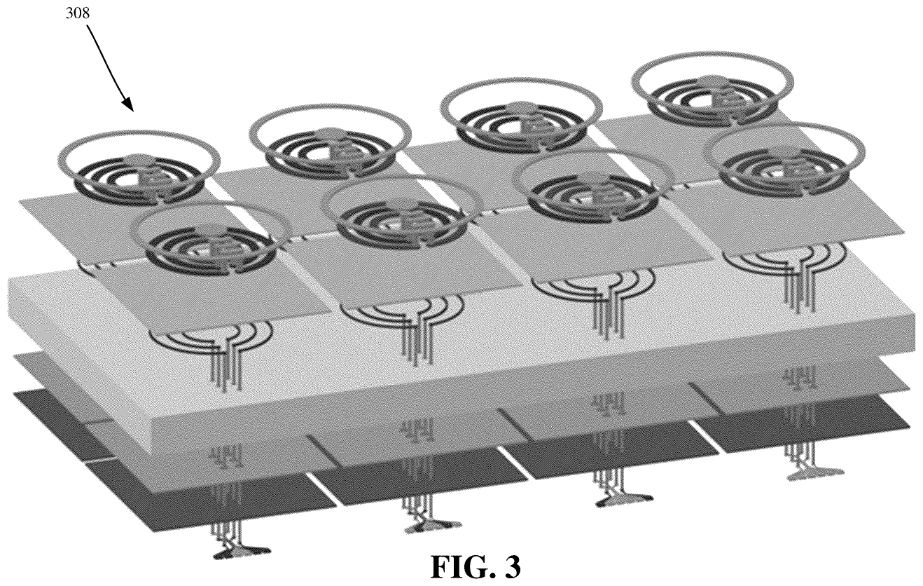

When assembled (fabricated), an array of such unit cells provides a metasurface 308, (corresponding to the metasurface 108 of FIG. 1), as shown in FIG. 3.

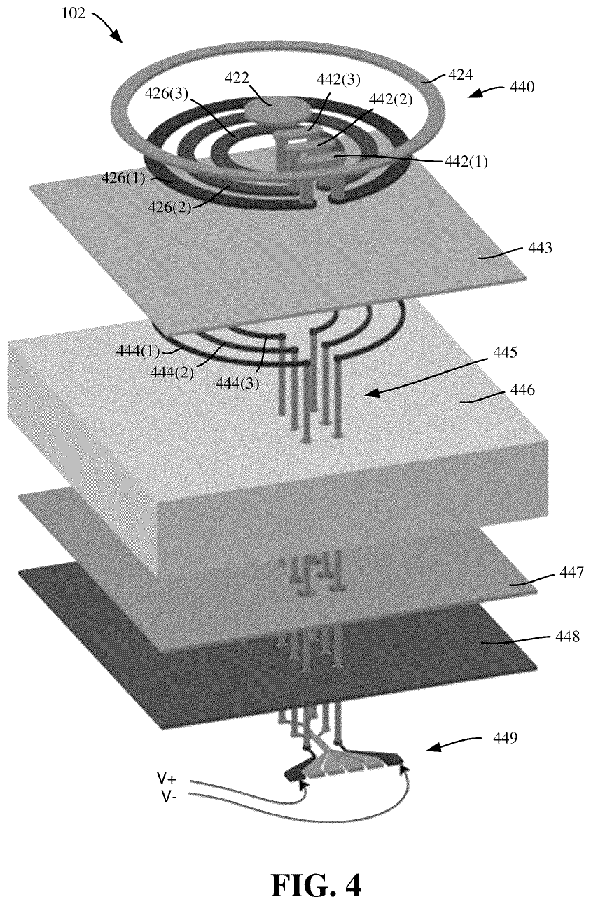

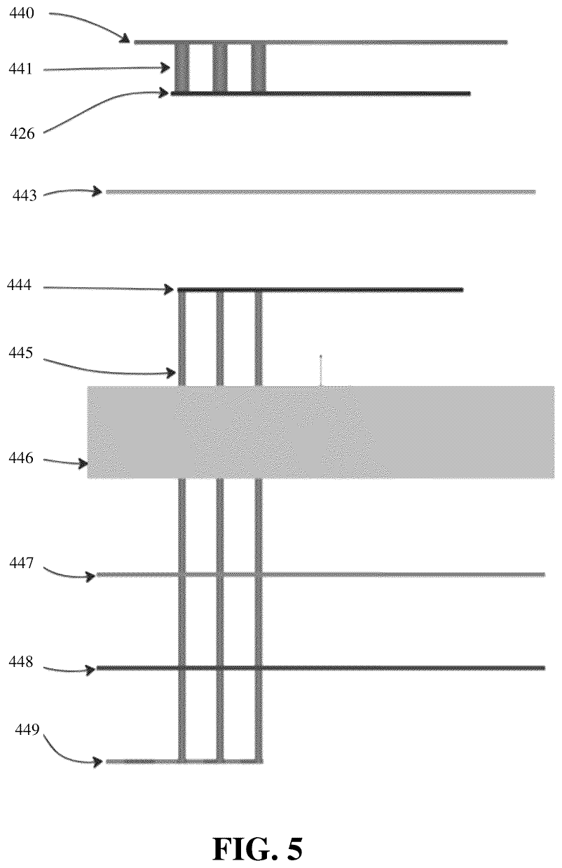

In one implementation generally shown in FIGS. 4 and 5, the unit cell 102 includes a metallization layer 440 and a metal interconnect layer 441 on which is formed a resonating pattern of metallic elements, such as including a ring-shaped resonator configured to resonate when the incoming electromagnetic (EM)/radio frequency (RF) wave is impinging on the unit cell 102, such as an RF signal near or within the millimeter wavelength, e.g., (above 25 gigahertz). In general, the metallic resonating pattern includes an inner metal patch 422, which in this example is disk-shaped, and an outer ring 424, which in this example is circular. Chalcogenide penannular rings 426(1)-426(3) (collectively labeled 426 in FIG. 5), coupled on their respective opposite ends to metal patches 442(1)-442(3) (in the metallization layer 440), respectively, can have their states controllably changed as described herein, which thereby various the phase response of the unit cell 102.

To control the unit cell's phase, heaters 444(1)-444(3) collectively labeled 444 in FIG. 5 beneath an upper dielectric layer 443 that allows heat to transferred through (e.g., SiNx (Silicon Nitride) or Aluminum nitride (AlN)) can be individually pulsed with voltage pulses that individually change the states of the chalcogenide penannular rings 426(1)-426(3) depending on the pulse voltage and time applied. Interconnects 445 through the various lower components described herein, including a substrate 446, and a lower dielectric layer 448, allow the voltage pulses to be applied to the heaters 444(1)-444(3) via corresponding pairs of the contact pads 449; two such contact pads are shown as having voltage (V+ and V−) applied.

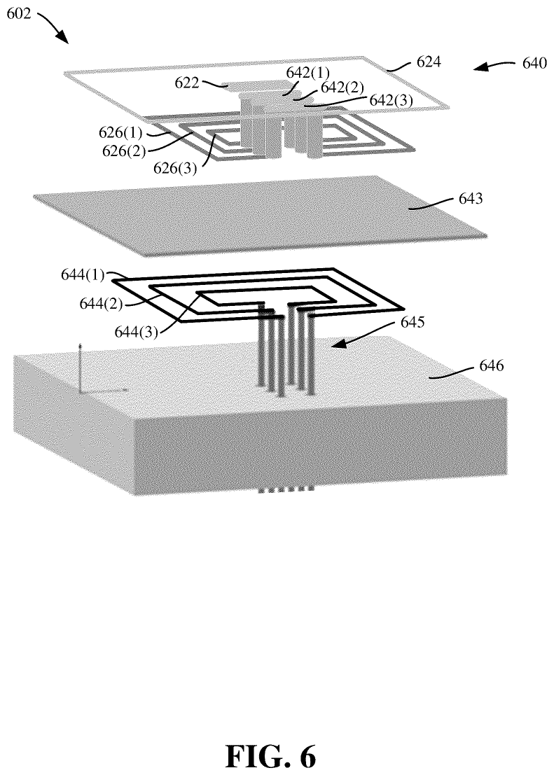

FIG. 6 shows an upper portion of a unit cell 602 similar to the unit cell 102 depicted in FIG. 4, in which similar elements are labeled 6xx instead of 4xx, while identical elements retain the same 4xx labeling. In general, the outer metallic resonating ring pattern 624 is rectangular shaped, as are the chalcogenide penannular rings 626(1)-626(3) and the heaters 664(1)-664(3). While any shape metallic patterns and chalcogenide elements can be used, as long as the resonator resonates at the designed resonance frequency, unlike circular elements, rectangular elements can be oriented differently, which can affect polarization.

Turning to heating phase change (chalcogenide) material to change its state from conductive (crystalline) state to nonconductive (amorphous) state and vice-versa, antimony telluride (SbTe) and germanium telluride (GeTe) are suitable phase change materials. GeSbTe can be tailored to offer more than six orders of magnitude change in material's resistivity with switching time on the order of sub-nanoseconds (ns), and thus provides electrical contrast between two than SbTe, for example, (which offers up to four orders of magnitude change in material's resistance with switching time on the order of sub-picoseconds). GeSbTe also offers ultra-low resistance in crystalline state, offering better electromagnetic waves interaction and low resistive losses which are more prominent in SbTe.

Switching between the two states can be achieved by applying thermal energy such as a pulse with certain amplitude and width (˜ns) through an electrically insulated high-speed heater. Note that such phase change material holds its state as long as it is not actuated with another either crystalline or amorphous pulse, whereby the technology described herein offers energy-efficient reconfigurability with multi-bit tunability, in that power is needed intermittently, that is, only during the reconfiguration phase when the heaters are actuated to change the state of the phase change material. Once the desired pattern is achieved, the material retains its state without the need for ongoing power.

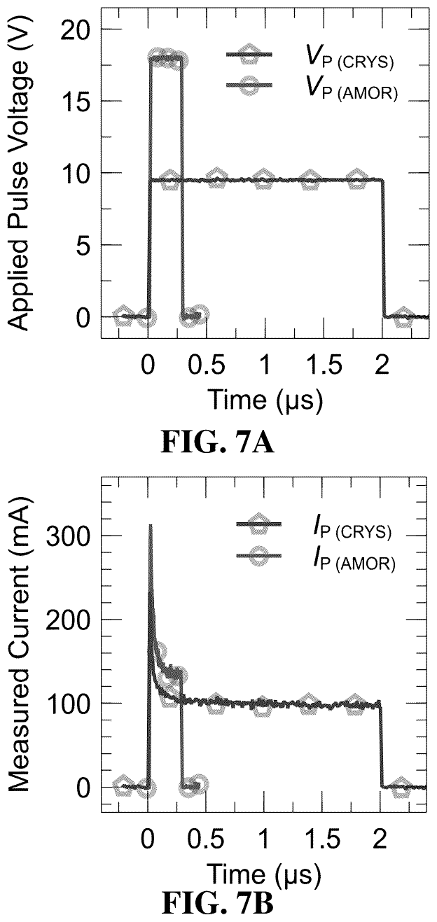

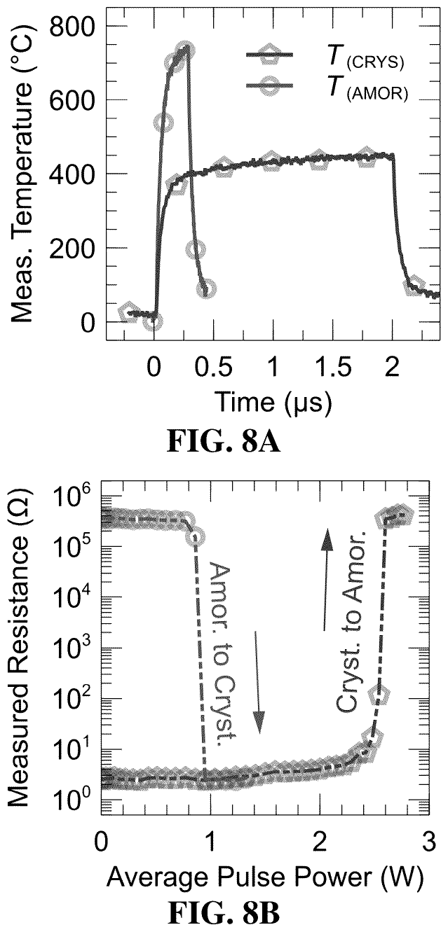

FIGS. 7A-8B show graphical representations of the pulse types for switch actuation. As can be seen in FIG. 7A which shows the distinct types of applied voltage pulses, a shorter duration (about 0.5 microseconds, or μS), higher voltage (around 18 Volts, or V) pulse Vp_{(AMOR)} changes the chalcogenide material to its nonconductive, amorphous state, whereas a longer duration (about 2.0 μS, lower voltage (around 7 V) pulse Vp_{(CRYS)} changes the chalcogenide material to its conductive, crystalline state. FIG. 7B shows the corresponding measured current levels in milliamps (mA), and FIG. 8A shows the corresponding measured temperature (measured temperature generated in refractory micro-heaters) in degrees Centigrade (° C.). FIG. 8B shows the changes in measured device resistance in Ohms (Ω) based on varied average pulse power in Watts (W).

FIG. 9 is a representation of an example unit cell with three rings that can be individually heated into eight different states, State 0-State 7. The inner chalcogenide rings are labeled 426(1) (outermost)-426(3) (innermost). When shown as a darker chalcogenide ring, the ring is in purely resistive state, that is, a V_{P(AMOR)} pulse to the respective contact pads change the conductivity (R1, R2, or R3) of a darker metallic ring to purely resistive, i.e., OFF or zero (0).

In contrast, applying a V_{P(CRYS)} pulse reverses the resistive change to conductive state, shown as the ON or one (1) states of the lighter metallic rings 426(1)-426(3). Thus, for example, the unit cell state shown in the upper row, second from the left, is in a State 1 (R1=0, R2=0, R3=1), corresponding to one phase shift, whereas the unit cell state shown in the lower row, second from the right, is in State 6 (R1=1, R2=1, R3=0), corresponding to a different phase shift. The other states can be similarly identified based on their state numbers and their (R1, R2, or R3) values.

To reiterate, the phase change process only consumes power during the transition phases (˜ns), and thus no static DC power consumption is required to hold the selected state.

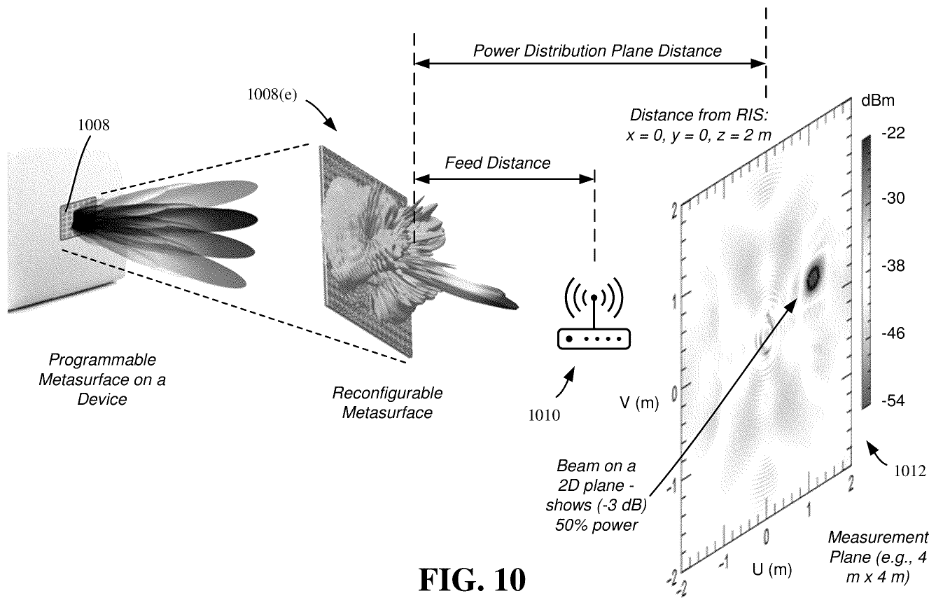

FIG. 10 is representation of an example scenario setup for power and beam distribution, in which a simulated antenna was used to generate an EM signal in a full-wave 3D simulator. In actual practice, the EM signal will be a radio wave from access point or base station. As can be seen, a programmable surface 1008 (shown enlarged as 1008(e)) on a device such as a radio or the like beams a beam to an access point or base station 1010. A 2D measurement plane 1012 is used in simulations to show how the beam is received.

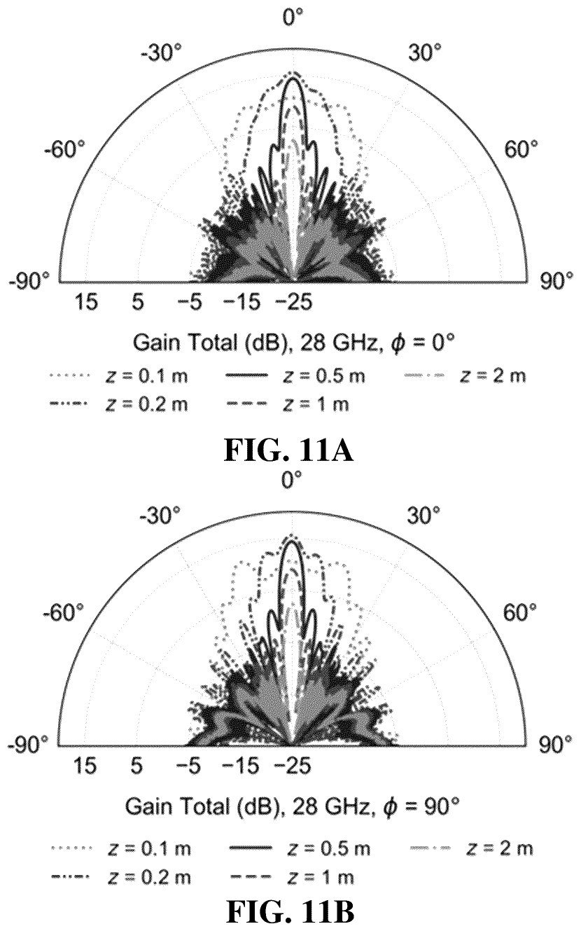

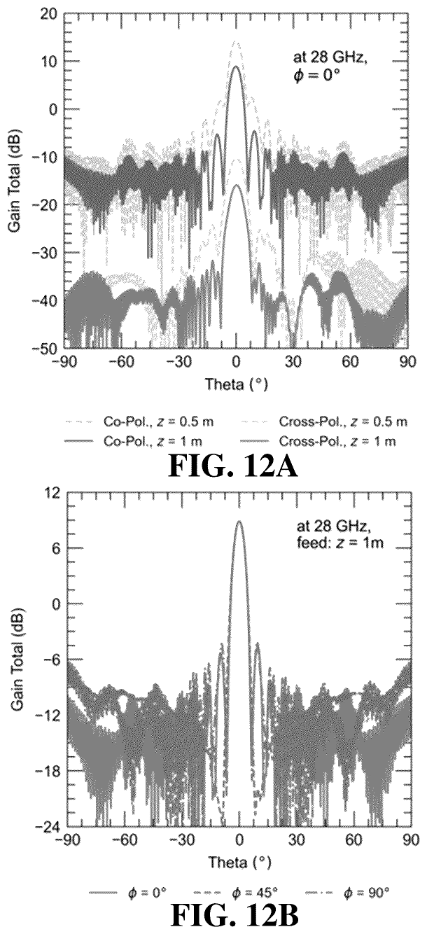

FIGS. 11A, 11B, 12A and 12B show gain and co-/cross-polarization performance results of an example simulation. In particular, the EM analyzed gain (in dB) at different φ° for different feed locations; the co-polarization and cross-polarization is greater than 28 dB.

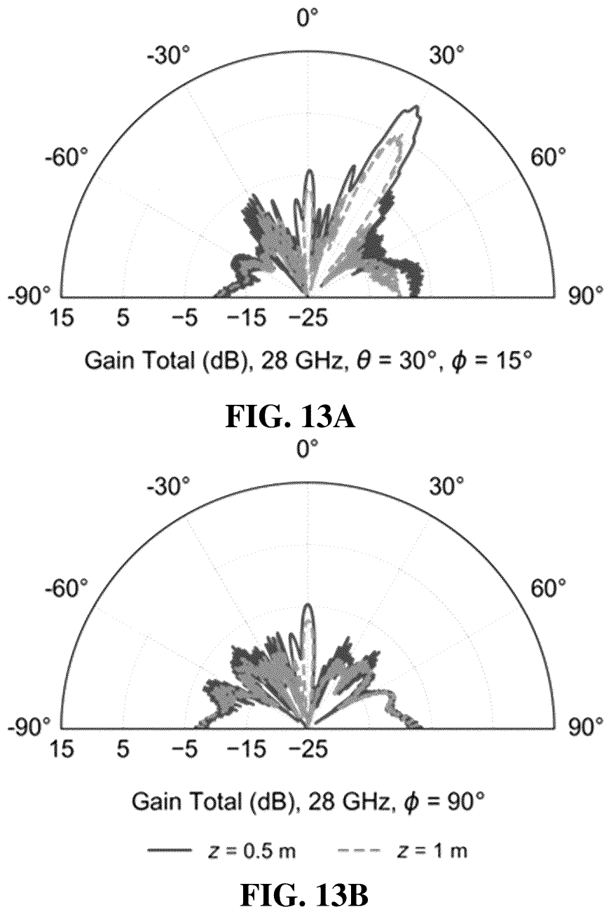

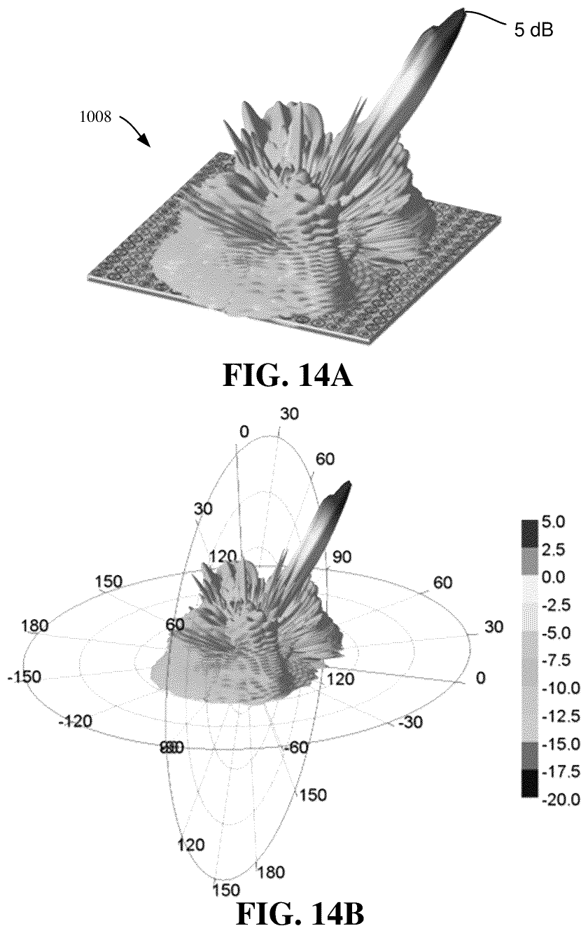

FIGS. 13A, 13B, 14A and 14B show example simulation gain and feed distance variation analysis for θ=30° and φ=15°. In FIG. 13A, the dimensions of the metasurface 1008 used are 10 cm×10 cm. In FIG. 13B, the feed location is x=0, y=0, z=0.5 millimeters (mm).

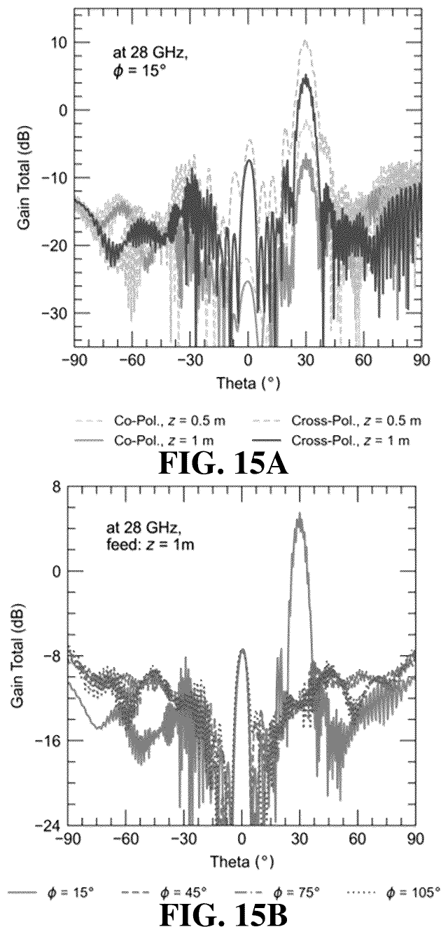

FIGS. 15A and 15B show electromagnetic (EM) analyzed gain (dB, FIGS. 13A, 13B) performance results of an example simulation at different φ° for different feed locations. The co-polarization and cross-polarization is greater than 12 dB.

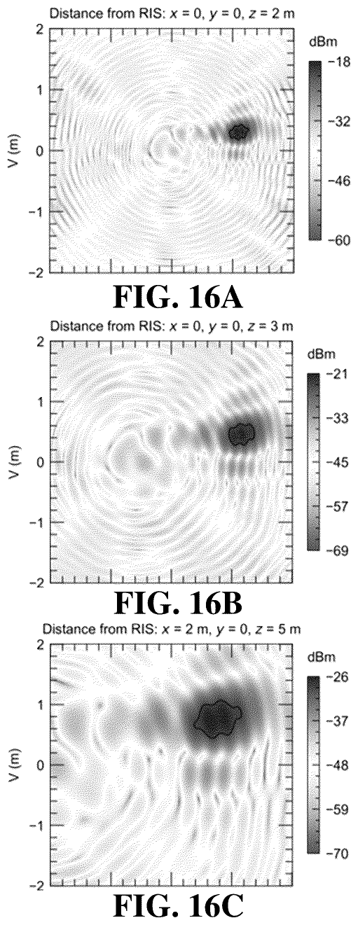

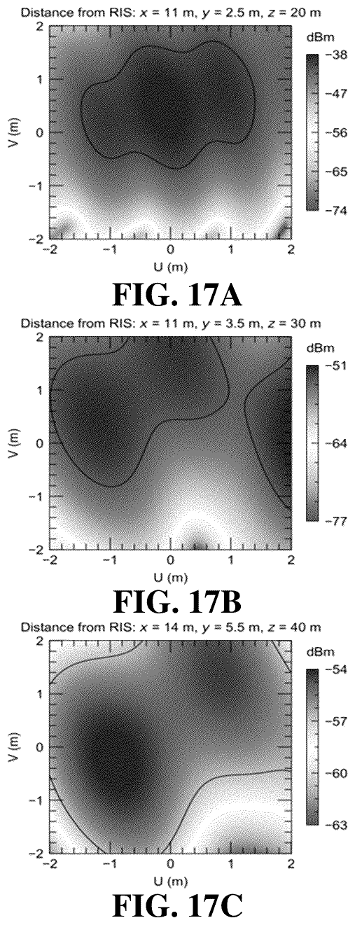

FIGS. 16A, 16B, 16C, 17A, 17B and 17B show example power and beam distribution plots of an example simulation at various distances. The feed antenna distance from the reflective metasurface is 0.5 m, with the 2D plane coordinates given above each plot.

One or more example embodiments can be embodied in a device, such as described and represented herein. The device can include a metallization layer including an outer conductive ring and an inner conductive patch, and a phase change material layer beneath the metallization layer. The phase change material layer can include a first inner ring area positioned between the outer conductive ring and the inner conductive patch, and a second inner ring area positioned between the first inner ring area and the inner patch. The device can include a heater network beneath the phase change material layer including a first heater element beneath the first inner ring area, and a second heater element beneath the second inner ring area, the heater network controllable to change at least one of: a first conductive state or a first resistive state of the first inner ring area by applying first heat energy to the first heater element, or change at least one of a second conductive state or a second resistive state of the second inner ring area by applying second heat energy to the second heater element. The first conductive state or the first resistive state of the first inner ring area, and the second conductive state or the second resistive state of the second inner ring area determine a phase response of the device with respect to redirecting an impinging electromagnetic wave as a redirected instance from the device.

The device further can include a third inner ring area positioned between the second inner ring area and the inner patch, wherein the heater network can include a third heater element beneath the third inner ring area, the heater network controllable to change a third conductive state or a third resistive state of the third inner ring area by applying third heat energy to the third heater element, wherein the third conductive state or the third resistive state of the third inner ring area further determine the phase of the device with respect to the redirecting of the impinging electromagnetic wave as the redirected instance.

The first inner ring area can be circular, and the first heater element can be circular and substantially similar in size to apply the first heat energy to the first inner ring area.

The first inner ring area can be rectangular, and the first heater element can be rectangular and substantially similar in size to apply the first heat energy to the first inner ring area.

The first inner ring area can be coupled via first interconnects to a first conductive portion of the metallization layer between, and electrically separated from, the outer conductive ring and the inner conductive patch, and wherein the second inner ring area can be coupled via second interconnects to a second conductive portion of the metallization layer between, and electrically separated from, the first conductive portion and the inner conductive patch.

The first inner ring area can be rectangular, and the first heater element can be rectangular and substantially similar in size to apply the first heat energy to the first inner ring area.

The device further can include a dielectric between the heater network beneath the phase change material layer.

The device further can include a substrate beneath the heater network.

The device further can include a metal ground plane beneath the substrate.

The phase change material layer can include at least one of: germanium telluride or antimony telluride.

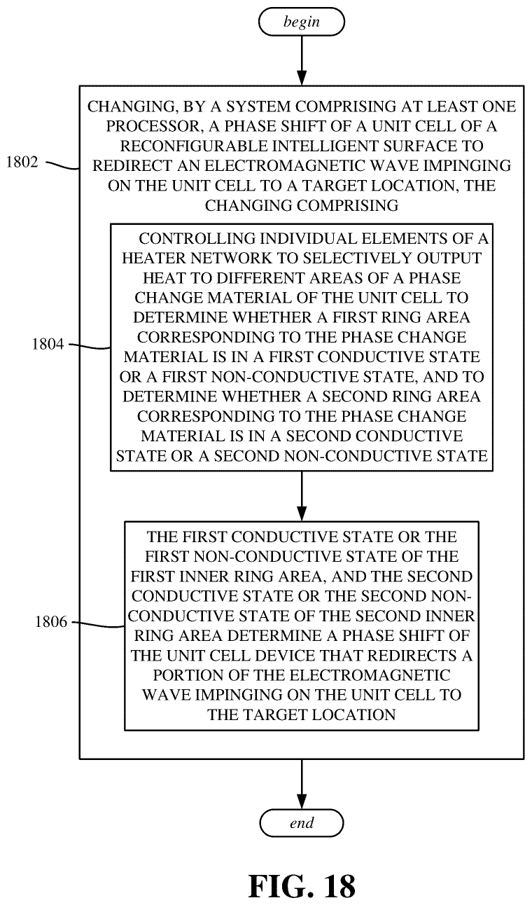

One or more example aspects, such as corresponding to example operations of a method, or a system/a machine-readable medium having executable instructions that, when executed by a processor, facilitate performance of the operations, can be represented in FIG. 18. Example operation 1802 represents changing, by a system comprising at least one processor, a phase shift of a unit cell of a reconfigurable intelligent surface to redirect an electromagnetic wave impinging on the unit cell to a target location. The changing can include example operation 1804, which represents controlling individual elements of a heater network to selectively output heat to different areas of a phase change material of the unit cell to determine whether a first ring area corresponding to the phase change material can be in a first conductive state or a first nonconductive state, and to determine whether a second ring area corresponding to the phase change material can be in a second conductive state or a second nonconductive state, in which (block 1806) the first conductive state or the first nonconductive state of the first inner ring area, and the second conductive state or the second nonconductive state of the second inner ring area determine a phase shift of the unit cell device that redirects a portion of the electromagnetic wave impinging on the unit cell to the target location.

The phase shift can be a first phase shift, the target location can be a first target location, and further operations can include obtaining, by the system, information representative of a second target location, and in response to the obtaining of the information, redirecting, by the system, the electromagnetic wave to the second location based on changing the first phase shift to a second phase shift, comprising controlling at least one of the individual elements of the heater network to change at least one of: the first ring area from the first conductive state to the first nonconductive state, or the first ring area from the first nonconductive state to the first conductive state, or the second ring area from the second conductive state to the second nonconductive state, or the second ring area from the second nonconductive state to the second conductive state.

The information can be first information, and further operations can include obtaining, by the system, second information representative of a third target location, and in response to the obtaining of the second information, redirecting, by the system, the electromagnetic wave to the third location based on changing the second phase shift to a third phase shift, which can include controlling at least one of the individual elements of the heater network to change at least one of: a third ring area from a third conductive state to a third nonconductive state, or the third ring area from the third nonconductive state to the third conductive state.

Controlling the individual elements of the heater network to selectively output the heat can include pulsing a selected heating element of the individual elements with a voltage or current pulse to set a portion of phase change material from a higher portion resistance to a lower resistance portion, the lower resistance portion corresponding to a location of the selected heating element.

One or more example embodiments can be embodied in a unit cell, such as described and represented herein. The unit cell can include a metallization layer including a metal outer ring, a metal inner patch, and a metal portion between the outer ring and the inner patch; the metal outer ring, a metal inner patch, and a metal portion can be insulated from one another. The unit cell can include a phase change material beneath the metallization layer, including a penannular ring area positioned between the metal outer ring and the metal inner patch, the penannular ring area coupled, on one end, to one side of the metal portion, and coupled on, an opposite end opposite the one end, to an opposite side of the metal portion opposite the one side. The unit cell can include a heating element that can be controlled to determine a phase shift of the unit cell, based on heating the phase change material to a conductive state that electrically couples the one end of the penannular ring area to the opposite end of the penannular ring area via the metal portion, or to a resistive state that electrically decouples the one end of the penannular ring area from the opposite end of the penannular ring area.

The penannular ring area can be circular, and the heater element can be circular.

The penannular ring area can be rectangular, and the heater element can be rectangular.

The phase change material layer can include at least one of: germanium telluride or antimony telluride.

The unit cell further can include a dielectric between the heating element beneath the phase change material layer, a substrate beneath the eating element, and a metal ground plane beneath the substrate.

The metal portion can be a first metal portion, the one side of the first metal portion can include a first side, the opposite side of the first metal portion can include a first opposite side, the penannular ring area can be a first penannular ring area, the one end of the first penannular ring area can be a first end of the first penannular ring area, the opposite end of the first penannular ring area can be a first opposite end of the penannular ring area, the heating element can be a first heating element, the conductive state can be a first conductive state, the resistive state can be a first resistive state, and the unit cell further can include a second metal portion between the first metal portion and the inner patch, in which the second metal portion can be insulated from the first metal portion, a second penannular ring area of the phase change material positioned between the first penannular ring area and the metal inner patch, the second penannular ring area coupled, on a second end, to a second side of the second metal portion, and coupled, on a second opposite end opposite the second end, to a second opposite side of the second metal portion opposite the second side, and a second heating element that can be controlled to determine the phase shift of the unit cell, based on heating the phase change material to a second conductive state that electrically couples the second end of the second penannular ring area to the second opposite end of the second penannular ring area via the second metal portion, or to a second resistive state that electrically decouples the second end of the penannular ring area from the second opposite end of the second penannular ring area.

The unit cell further can include a third metal portion between the second metal portion and the inner patch, in which the third metal portion can be insulated from the second metal portion, a third penannular ring area of the phase change material positioned between the second penannular ring area and the metal inner patch, the third penannular ring area coupled, on a third end, to a third side of the third metal portion, and coupled, on a third opposite end opposite the third end, to a third opposite side of the third metal portion opposite the third side, and a third heating element that can be controlled to determine the phase shift of the unit cell, based on heating the phase change material to a third conductive state that electrically couples the third end of the third penannular ring area to the third opposite end of the third penannular ring area via the third metal portion, or to a third resistive state that electrically decouples the third end of the penannular ring area from the third opposite end of the third penannular ring area.

As can be seen, the technology described herein is directed to an intelligent reconfigurable surface arranged with unit cells that can be reconfigured dynamically based on applying voltage pulses to phase change material. The material can be monolithically integrated with a resistive heating matrix, which facilitates efficiency, scalability, and ease of integration of precise, fully-integrated and real-time programmable metasurfaces.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A device, comprising:
a metallization layer comprising an outer conductive ring and an inner conductive patch;
a phase change material layer beneath the metallization layer, comprising:
a first inner ring area positioned between the outer conductive ring and the inner conductive patch, and
a second inner ring area positioned between the first inner ring area and the inner patch; and
a heater network beneath the phase change material layer comprising a first heater element beneath the first inner ring area, and a second heater element beneath the second inner ring area, the heater network controllable to change at least one of: a first conductive state or a first resistive state of the first inner ring area by applying first heat energy to the first heater element, or change at least one of a second conductive state or a second resistive state of the second inner ring area by applying second heat energy to the second heater element,
wherein the first conductive state or the first resistive state of the first inner ring area, and the second conductive state or the second resistive state of the second inner ring area determine a phase response of the device with respect to redirecting an impinging electromagnetic wave as a redirected instance from the device.

2. The device of claim 1, further comprising a third inner ring area positioned between the second inner ring area and the inner patch, wherein the heater network comprises a third heater element beneath the third inner ring area, the heater network controllable to change a third conductive state or a third resistive state of the third inner ring area by applying third heat energy to the third heater element, wherein the third conductive state or the third resistive state of the third inner ring area further determine the phase of the device with respect to the redirecting of the impinging electromagnetic wave as the redirected instance.

3. The device of claim 1, wherein the first inner ring area is circular, and wherein the first heater element is circular and substantially similar in size to apply the first heat energy to the first inner ring area.

4. The device of claim 1, wherein the first inner ring area is rectangular, and wherein the first heater element is rectangular and substantially similar in size to apply the first heat energy to the first inner ring area.

5. The device of claim 1, wherein the first inner ring area is coupled via first interconnects to a first conductive portion of the metallization layer between, and electrically separated from, the outer conductive ring and the inner conductive patch, and wherein the second inner ring area is coupled via second interconnects to a second conductive portion of the metallization layer between, and electrically separated from, the first conductive portion and the inner conductive patch.

6. The device of claim 1, wherein the first inner ring area is rectangular, and wherein the first heater element is rectangular and substantially similar in size to apply the first heat energy to the first inner ring area.

7. The device of claim 1, further comprising a dielectric between the heater network beneath the phase change material layer.

8. The device of claim 1, further comprising a substrate beneath the heater network.

9. The device of claim 8, further comprising a metal ground plane beneath the substrate.

10. The device of claim 1, wherein the phase change material layer comprises at least one of: germanium telluride or antimony telluride.

11. A method, comprising,
changing, by a system comprising at least one processor, a phase shift of a unit cell of a reconfigurable intelligent surface to redirect an electromagnetic wave impinging on the unit cell to a target location, the changing comprising:
controlling individual elements of a heater network to selectively output heat to different areas of a phase change material of the unit cell to determine whether a first ring area corresponding to the phase change material is in a first conductive state or a first nonconductive state, and to determine whether a second ring area corresponding to the phase change material is in a second conductive state or a second nonconductive state,
wherein the first conductive state or the first nonconductive state of the first inner ring area, and the second conductive state or the second nonconductive state of the second inner ring area determine a phase shift of the unit cell device that redirects a portion of the electromagnetic wave impinging on the unit cell to the target location.

12. The method of claim 11, wherein the phase shift is a first phase shift, wherein the target location is a first target location, and further comprising:
obtaining, by the system, information representative of a second target location, and
in response to the obtaining of the information, redirecting, by the system, the electromagnetic wave to the second location based on changing the first phase shift to a second phase shift, comprising controlling at least one of the individual elements of the heater network to change at least one of:
the first ring area from the first conductive state to the first nonconductive state, or the first ring area from the first nonconductive state to the first conductive state, or
the second ring area from the second conductive state to the second nonconductive state, or the second ring area from the second nonconductive state to the second conductive state.

13. The method of claim 12, wherein the information is first information, and further comprising:
obtaining, by the system, second information representative of a third target location, and
in response to the obtaining of the second information, redirecting, by the system, the electromagnetic wave to the third location based on changing the second phase shift to a third phase shift, comprising controlling at least one of the individual elements of the heater network to change at least one of: a third ring area from a third conductive state to a third nonconductive state, or the third ring area from the third nonconductive state to the third conductive state.

14. The method of claim 11, wherein the controlling of the individual elements of the heater network to selectively output the heat comprises pulsing a selected heating element of the individual elements with a voltage or current pulse to set a portion of phase change material from a higher portion resistance to a lower resistance portion, the lower resistance portion corresponding to a location of the selected heating element.

15. A unit cell, comprising:
a metallization layer comprising a metal outer ring, a metal inner patch, and a metal portion between the outer ring and the inner patch, wherein the metal outer ring, a metal inner patch, and a metal portion are insulated from one another;
a phase change material beneath the metallization layer, comprising a penannular ring area positioned between the metal outer ring and the metal inner patch, the penannular ring area coupled, on one end, to one side of the metal portion, and coupled on, an opposite end opposite the one end, to an opposite side of the metal portion opposite the one side; and
a heating element that is controlled to determine a phase shift of the unit cell, based on heating the phase change material to a conductive state that electrically couples the one end of the penannular ring area to the opposite end of the penannular ring area via the metal portion, or to a resistive state that electrically decouples the one end of the penannular ring area from the opposite end of the penannular ring area.

16. The unit cell of claim 15, wherein the penannular ring area is circular, and wherein the heater element is circular.

17. The unit cell of claim 15, wherein the penannular ring area is rectangular, and wherein the heater element is rectangular.

18. The unit cell of claim 15, further comprising a dielectric between the heating element beneath the phase change material layer, a substrate beneath the eating element, and a metal ground plane beneath the substrate.

19. The unit cell of claim 15, wherein the metal portion is a first metal portion, wherein the one side of the first metal portion comprises a first side, wherein the opposite side of the first metal portion comprises a first opposite side, wherein the penannular ring area is a first penannular ring area, wherein the one end of the first penannular ring area is a first end of the first penannular ring area, wherein the opposite end of the first penannular ring area is a first opposite end of the penannular ring area, wherein the heating element is a first heating element, wherein the conductive state is a first conductive state, wherein the resistive state is a first resistive state, and further comprising:
a second metal portion between the first metal portion and the inner patch, wherein the second metal portion is insulated from the first metal portion;
a second penannular ring area of the phase change material positioned between the first penannular ring area and the metal inner patch, the second penannular ring area coupled, on a second end, to a second side of the second metal portion, and coupled, on a second opposite end opposite the second end, to a second opposite side of the second metal portion opposite the second side; and
a second heating element that is controlled to determine the phase shift of the unit cell, based on heating the phase change material to a second conductive state that electrically couples the second end of the second penannular ring area to the second opposite end of the second penannular ring area via the second metal portion, or to a second resistive state that electrically decouples the second end of the penannular ring area from the second opposite end of the second penannular ring area.

20. The unit cell of claim 15, further comprising:
a third metal portion between the second metal portion and the inner patch, wherein the third metal portion is insulated from the second metal portion;
a third penannular ring area of the phase change material positioned between the second penannular ring area and the metal inner patch, the third penannular ring area coupled, on a third end, to a third side of the third metal portion, and coupled, on a third opposite end opposite the third end, to a third opposite side of the third metal portion opposite the third side; and
a third heating element that is controlled to determine the phase shift of the unit cell, based on heating the phase change material to a third conductive state that electrically couples the third end of the third penannular ring area to the third opposite end of the third penannular ring area via the third metal portion, or to a third resistive state that electrically decouples the third end of the penannular ring area from the third opposite end of the third penannular ring area.
